(19) United States
(12) Patent Application Publication
(10) Pub. No.: US 2008/0308839 A1
(43) Pub. Date: Dec. 18, 2008

(54) INSULATED GATE BIPOLAR TRANSISTOR

(75) Inventor: Kikuo Okada, Saitama (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-Shi (JP); SANYO Semiconductor Co., Ltd., Ora-Gun (JP)

(21) Appl. No.: 12/137,054

(22) Filed: Jun. 11, 2008

(30) Foreign Application Priority Data
Jun. 12, 2007 (JP) 2007-155470

(51) Int. Cl. H01L 29/70

(52) U.S. Cl. 257/133; 257/E29.171

(57) ABSTRACT

The invention realizes IGBT having an NPT structure which has a smaller variation in switching characteristics and the like and lower on-resistance. In the IGBT of the invention, by setting a ratio of a width of a trench to an interval between the trenches within a range of 1 to 2, electron current density and a conductivity modulation effect are optimized, a breakdown voltage is secured, a variation in characteristics is minimized, and on-resistance is largely reduced.

### CROSS-REFERENCE OF THE INVENTION

This application claims priority from Japanese Patent Application No. 2007-155470, the content of which is incorporated herein by reference in its entirety.

### BACKGROUND OF THE INVENTION

1. Field of the Invention

The invention relates to an insulated gate bipolar transistor, particularly, an insulated gate bipolar transistor having a trench structure.

2. Description of the Related Art

An insulated gate bipolar transistor is called IGBT, which is one of general high-current switches. FIG. 7A shows a cross-sectional view of a conventional trench-type IGBT having a punch-through (PT) structure.

An IGBT 51 having a PT structure is configured so that an N⁻-type buffer layer 62 and an N⁻-type drift layer 53 are formed on a collector layer 60 made of a P⁺-type semiconductor substrate by epitaxial growth in this order. A P-type base layer 54 is formed on the front surface of the drift layer 53, and a plurality of trenches 52 is formed from the front surface of the base layer 54 to the drift layer 53. Although this figure shows the trenches 52 formed in only two positions for simplification, actually the plurality of trenches 52 is formed at given intervals so as to form stripes in a plan view. Gate oxide films 55 are formed inside these trenches 52 and gate electrodes 56 are embedded in the trenches 52 with these gate oxide films 55 being interposed therebetween, thereby forming insulated gates. N-type emitter layers 57 are further formed on the front surface of the base layer 54 adjacent to the insulated gates. Interlayer insulation films 59 are formed so as to cover the insulated gates and expose the emitter layers 57, and an emitter electrode 58 is formed so as to contact the emitter layers 57.

Generally, in the IGBT, the drift layer is formed thick by epitaxial growth so that a depletion layer does not reach the collector layer at a desired breakdown voltage. In the IGBT 51 having the PT structure, however, since the buffer layer 62 functions as a stopper terminating the depletion layer, the drift layer 53 is thinned for that amount. In detail, in the IGBT 51 having the PT structure, for obtaining a breakdown voltage of 600V, the drift layer 53 is formed to have a thickness of about 60 μm by epitaxial growth.

In the IGBT 51 having this structure, an attempt has been made to increase the cell density by forming the trenches 52 with high density in order to reduce the on-resistance. In detail, forming the trenches 52 with high density leads to formation of channels with high density, and thus enhances the electron current density and reduces the on-resistance. Reducing a width W1 of each of the trenches 52 and an interval W2 between the trenches 52 leads to the formation of the trenches 52 with high density. Actually, however, the reduction of the width W1 of each of the trenches 52 has been made to form the trenches 52 with high density. This is because the narrow interval W2 between the trenches 52 may cause connection between the adjacent emitter layers 57. Accordingly, the trenches 52 are formed so as to have the width W1 narrower than the interval W2 between the trenches 52. For example, the width W1 of each of the trenches 52 is about 0.3 times as large as the interval W2 between the trenches 52.

As described above, when a high breakdown voltage is required, the drift layer 53 needs a thickness corresponding to this voltage. In this regard, since the drift layer 53 is formed by epitaxial growth in the PT type IGBT 51, the cost increases according as the thickness increases. In order to avoid this, in recent years a non-punch-through (NPT) structure where the drift layer is made of a low-cost FZ wafer has been employed for the IGBT requiring a high breakdown voltage.

FIG. 7B is a cross-sectional view of the conventional trench-type IGBT having the NPT structure.

In the IGBT 71 having the NPT structure, a drift layer 73 is formed by grinding a FZ (Float Zoning) wafer, corresponding to a desired breakdown voltage. A collector layer 80 is formed by implanting a low dose of P⁺-type impurity in the drift layer 73. Differing from the IGBT 51 having the PT structure, the buffer layer 62 is not formed in the IGBT 71 having the NPT structure, and thus the drift layer 73 requires a thickness of about 100 μm for obtaining a breakdown voltage of 600V. In the IGBT 71 having the NPT structure, however, since the collector layer 80 is formed by ion implantation, the whole device of the NPT structure is thinner than that of the PT structure.

In the similar manner to the PT structure, the trenches 72 are also formed with high density in the NPT structure to enhance the electron current density. In the NPT structure, however, since the collector 80 is formed by ion implantation as described above, the amount of holes injected from the collector layer 80 to the drift layer 73 is smaller than in the PT structure by several digits. Therefore, the NPT structure is more affected by discharge of holes from the emitter electrode 78 contacting the base layer 74 between the trenches 72, and thus conductivity modulation tends to work less effectively.

Therefore, conventionally, like the IGBT 81 shown in FIG. 8, the discharging amount of holes is minimized by forming an interlayer insulation film 82 so as to insulate the emitter electrode 78 from the base layer 74 on a region between the predetermined trenches 72 in the state where the trenches 72 are formed with high density. The relevant technique is described in Japanese Patent Application Publication No. 2000-58833.

In the IGBT 81 shown in FIG. 8, however, the potential of the base layer 74 in a region between the trenches 72 formed with the interlayer insulation film 82 thereabove floats, easily causing a variation in characteristics. In detail, holes are not influenced by the potential barrier between the base layer 74 and the drift layer 73 since these are the minority carriers in the drift layer 73. Therefore, during the on state of the IGBT 81, the holes enter the base layer 74 covered by the interlayer insulation film 82 from the collector layer 80, and the potential in this portion changes accordingly. Furthermore, during the off state of the IGBT 81, it is difficult to control the discharge of the holes entering this portion, thereby causing a variation in switching characteristics.

An objective of the invention is to improve the characteristics by an idea of enhancing the conductivity modulation effect by increasing the trench width W1 relative to the minimum width of the trench interval W2, which is unimaginable from and stands in contrast to the conventional idea of improving the characteristics by enhancing the electron current density by minimizing W1/W2(the optimum value W1/W2=0.3 described in this specification).

### SUMMARY OF THE INVENTION

The invention provides a non-punch-through type insulated gate bipolar transistor including: a first conductive type collector layer; a second conductive type drift layer formed on the collector layer; a first conductive type base layer formed on a front surface of the drift layer; a plurality of insulated gates formed from a front surface of the base layer to the drift layer; and a second conductive type emitter layer formed on the front surface of the base layer adjacent to the insulated gates, wherein a width of the insulated gate is larger than a minimum interval between the insulated gates.

### BRIEF DESCRIPTION OF THE DRAWINGS

FIG. 1A shows a plan view of IGBT of an embodiment of the invention.

FIG. 1B shows a cross-sectional view of IGBT of an embodiment of the invention.

FIG. 2 shows conditions of IGBT for evaluation.

FIG. 3 shows a variation in a saturation voltage relative to trench width ratios.

FIG. 4 shows a variation in hole density distribution in a drift layer by differences in the trench width ratio.

FIGS. 5A and 5B show a variation in field intensity distribution by a difference in the trench width ratio.

FIG. 6 shows a variation in a waveform of an emitter-collector breakdown voltage by differences in the trench width ratio.

FIGS. 7A and 7B show cross-sectional views of a conventional IGBT.

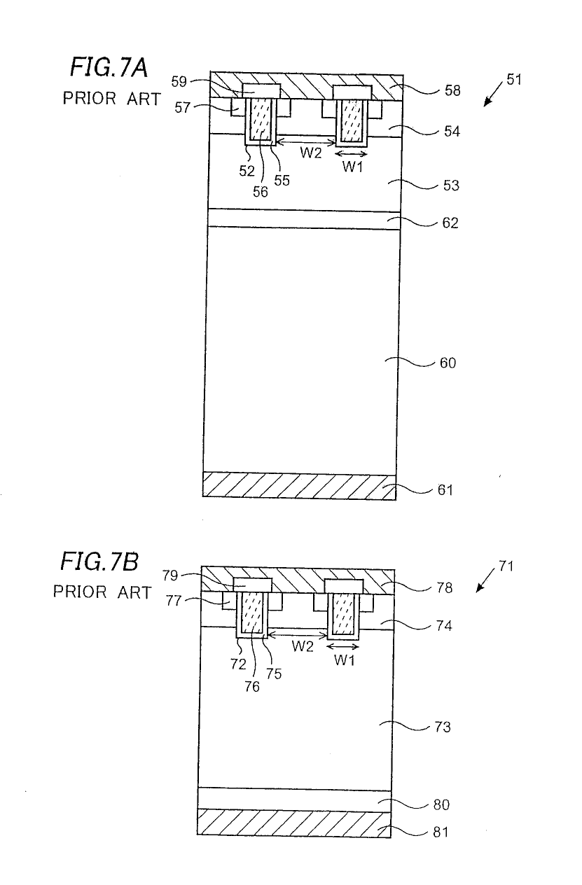

FIG. 8 shows a cross-sectional view of a conventional IGBT.

### DETAILED DESCRIPTION OF THE INVENTION

An embodiment of an insulated gate bipolar transistor of the invention will be described referring to figures in detail.

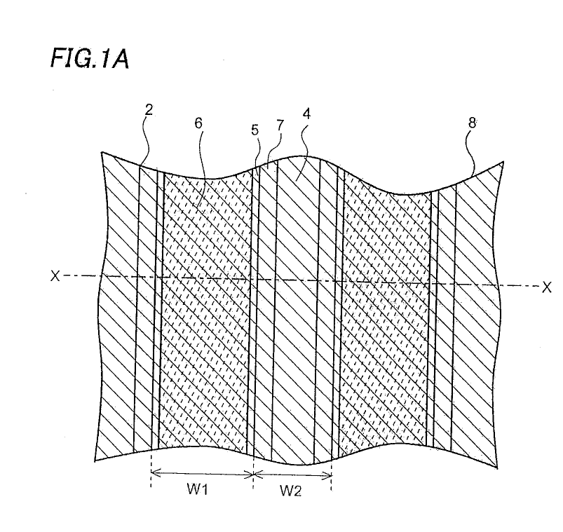

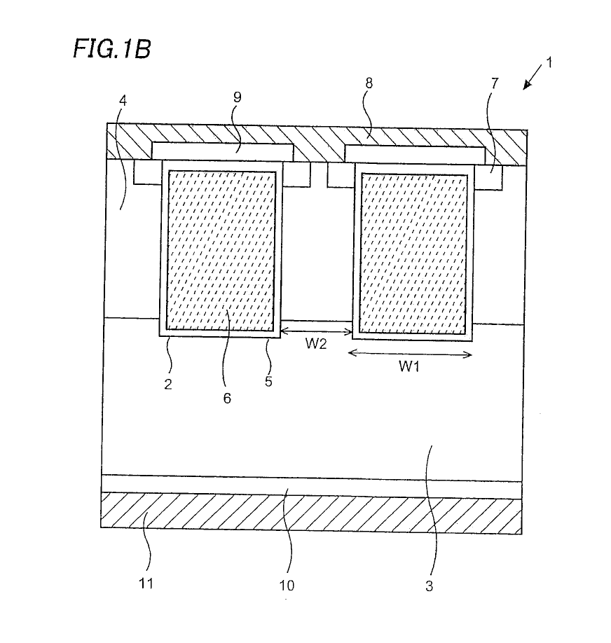

FIG. 1A shows a plan view of a trench-type IGBT 1 having an NPT structure of the embodiment. FIG. 1B shows a cross sectional view of a section X-X shown in FIG. 1A. Although FIG. 1 shows only two trenches 2 formed in two positions for simplification, actually a plurality of trenches 2 is formed at given intervals so as to form stripes in a plan view.

The IGBT 1 includes an N⁻ drift layer 3 made of a FZ wafer, a P-type base layer 4 formed on the front surface of the drift layer 3, a plurality of trenches 2 formed from the front surface of the base layer 4 to the drift layer 3, insulated gates configured by forming gate electrodes 6 inside the trenches 2 with gate oxide films 5 being interposed therebetween, N⁺-type emitter layers 7 formed on the front surface of the base layer 4 adjacent to the insulated gates, an emitter electrode 8 contacting the emitter layers 7, interlayer insulation films 9 insulating the gate electrodes 6 from the emitter electrode 8, and a P⁺-type collector layer 10 formed by ion implantation in the drift layer 3 on the back surface side. Here, conductivity types such as P⁺, P and P⁻ belong in one general conductivity type, and conductivity types such as N⁺, N and N⁻ belong in another general conductivity type.

In this structure, the drift layer 3 needs such a thickness as to prevent a depletion layer from reaching the collector layer 10 at a desired breakdown voltage. In the IGBT of the embodiment, for obtaining a breakdown voltage of 600 V, for example, the drift layer 3 is formed by grinding a FZ wafer so as to have a thickness of about 100 μm.

Furthermore, the impurity concentration of the collector layer 10 is adjusted corresponding to desired switching characteristics. For example, the collector layer 10 is ion-implanted so that the peak value of the impurity concentration is about 1×10¹⁰ cm⁻³.

The IGBT 1 of the embodiment is characterized by a structure in which a width W1 of each of the trenches 2 is larger than an interval W2 between the trenches 2 and less than double the interval W2. Details will be given below.

In this structure, the IGBT 1 of the embodiment operates in on/off states respectively as follow.

The operation of the IGBT 1 in the on state will be described first. The emitter electrode 8 is connected to the ground, and a positive voltage is applied to the collector electrode 11. Then, the PN junction between the drift layer 3 and the base layer 4 is reverse biased. In this state, however, when a positive voltage at a threshold between the gate electrodes 6 and the emitter electrode 8 or more is applied to the gate electrodes 6, N-type inverted channels are formed in the base layer 4 along the gate electrodes 6. Therefore, electrons are injected from the emitter layers 7 into the drift layer 3 through the channels. Accordingly, the PN junction between the collector layer 10 and the n-type drift layer 3 is forward biased, and holes are injected from the collector layer 10 into the drift layer 3. Then, conductivity modulation occurs in the drift layer 3 to reduce the resistance of the drift layer 3.

The IGBT 1 of the embodiment minimizes reduction of electron current density and provides sufficient conductivity modulation without a variation in characteristics. Details will be given below.

Next, the operation of the IGBT 1 in the off state will be described. When the voltage between the gate electrodes 6 and the emitter electrode 8 is lowered to less than the threshold, the channels formed along the gate electrodes 6 disappear. Then, electrons stop flowing from the emitter layers 7 in the drift layer 3, and accordingly holes stop flowing from the collector electrode 10 in the drift layer 3. Electrons and holes remaining in the drift layer 3 are then discharged from the collector electrode 11 and the emitter electrode 8 respectively, and recombine into a current.

As described above, the width W1 of the trench 2 is larger than the interval W2 between the trenches 2 and less than double the interval W2. Hereafter, the effect of this structure will be described.

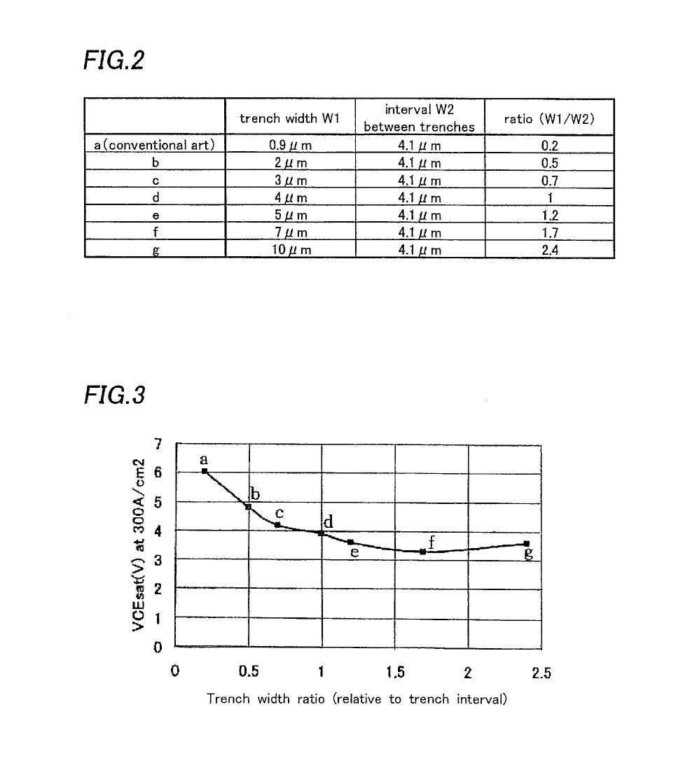

FIG. 2 shows conditions of the width W1 of the trench 2 and the interval W2 between the trenches 2 for evaluation described below. The evaluation is performed under seven conditions a to g in which a ratio of the width W1 of the trench 2 to the interval W2 between the trenches 2 (W1/W2) is varied within a range of 0.2 to 2.4. The condition a corresponds to a condition of a conventional IGBT where electron current density is optimized.

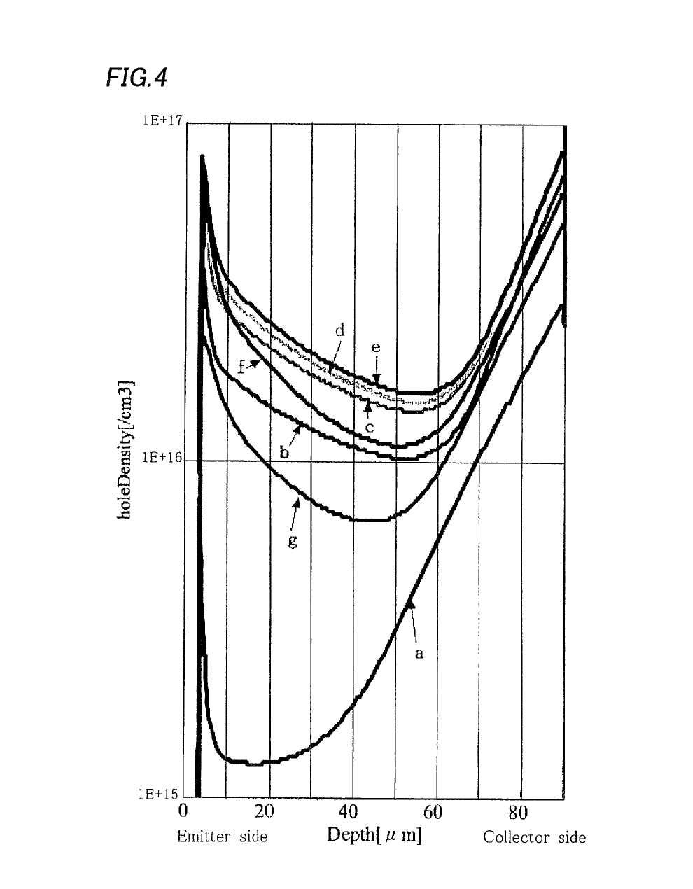

FIG. 3 shows the ratios (W1/W2) and a variation of a saturation voltage (VCEₛₐₜ) which corresponds to the on-resistance of the IGBT 1 by the ratios.

As a result of the evaluation, under the condition a, the VCEₛₐₜ is about 6V when the ratio (W1/W2) is about 0.2, showing the characteristics of the conventional IGBT. Under the conditions b to f, the VCEₛₐₜ decreases by about 2.7 V in total. Under the conditions f to g, however, the VCEₛₐₜ increases by about 0.3 V.

It is considered that the main cause of this is the NPT structure of the IGBT 1 of the embodiment.

In detail, in the IGBT 1, the VCEₛₐₜ is largely influenced not only by the electron current density but also by the conductivity modulation effect by injection of holes. In this regard, since the electron current density depends on the channel density, the electron current density is improved by reducing the ratio (W1/W2). In the PT structure, since the collector layer 10 is made of a P-type semiconductor substrate of a high concentration, the density of holes accumulated in the drift layer 3 is not largely influenced by changing the ratio (W1/W2). Therefore, the ratio (W1/W2) is set within a range less than 1.

On the other hand, since the IGBT 1 of the embodiment is of the NPT structure, the collector layer 10 is formed by ion implantation. Therefore, the amount of holes in the collector layer largely differs between the PT structure and the NPT structure. In detail, in the PT structure, the collector layer is formed to have a thickness of 100 to 150 μm with an impurity concentration of 2×10¹⁸ cm⁻³. In the NPT structure, the collector layer 10 is formed to have a thickness of about 0.5 μm with an impurity concentration of about 1×10¹⁰ cm⁻³. Accordingly, the amount of holes injected into the drift layer 3 is smaller than in the PT structure by several digits. Therefore, the NPT structure is more influenced than the PT structure by the discharge of holes from the emitter electrode 8 through between the trenches 2 by the reduced ratio (W1/W2).

From this evaluation result, it is considered that the conductivity modulation effect of the NPT structure is hardly degraded when the ratio (W1/W2) is over 1. Furthermore, when the ratio (W1/W2) is over 2, the NPT structure is largely influenced by the reduction of the electron current density.

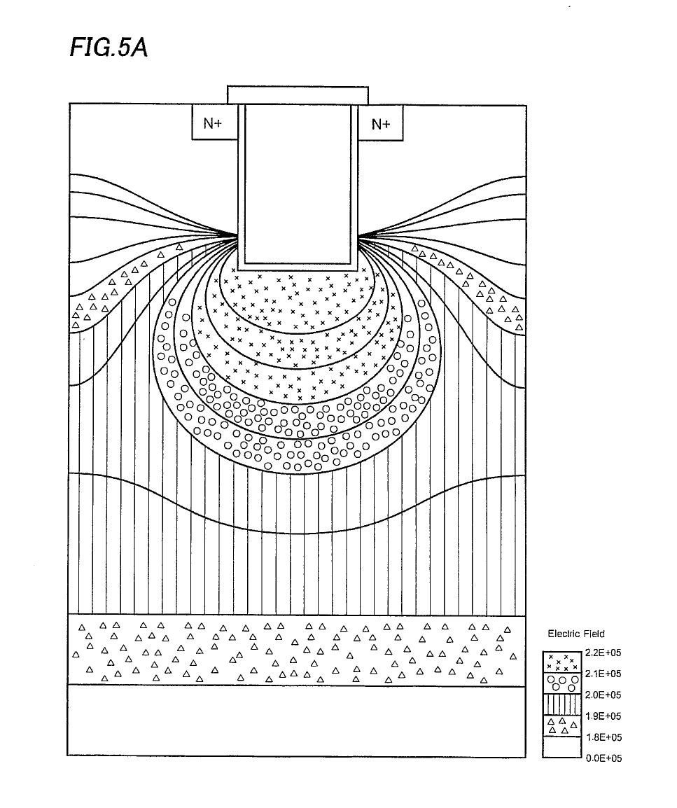

FIG. 4 shows a distribution chart of hole density relative to the depth of the drift layer 3. The axis of abscissas represents the depth from the boundary between the drift layer 3 and the base layer 4 as an origin.

Referring to this distribution chart, the amount of holes accumulated in the drift layer 3 increases from the condition a to the condition e. This is because the holes become more difficult to be discharged from the emitter electrode 8 as the ratio (W1/W2) increases more.

However, from the condition f to the condition g, the amount of holes accumulated in the drift layer 3 decreases. The holes become more difficult to be discharged from the emitter electrode 8 from the condition f to the condition g. However, it is considered that the decrease occurs because the amount of electrons entering the drift layer 3 decreases due to reduction of the channel density in this range and thus holes also become difficult to enter the drift layer 3 from the collector layer 10.

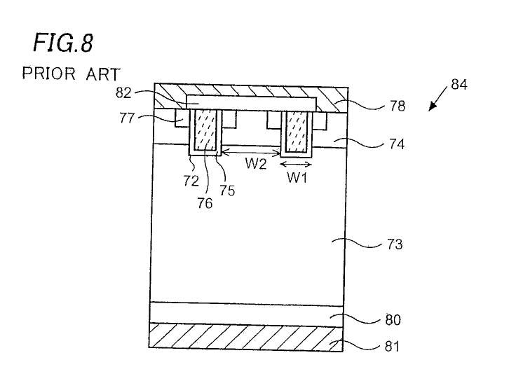

As described above, it is understood by this evaluation that changing the ratio (W1/W2) provides the same effect as in a case where an interlayer insulation film 82 is formed on a region between predetermined trenches 72 in the state where the trenches 72 are formed with high density as in the conventional structure shown in FIG. 8. Furthermore, it is understood that the on-resistance depending on the balance of the electron current density and the conductivity modulation effect is optimized by setting the ratio (W1/W2) within a range of 1 to 2 when the collector layer 10 is formed by ion implantation.

Generally, the IGBT needs a high breakdown voltage when a large positive voltage is applied to the collector electrode relative to the emitter electrode in the state where a lower voltage than the threshold is applied to the gate electrodes. A depletion layer expands in the drift layer from the base layer toward the collector layer in this voltage applying state. For securing a high breakdown voltage at this time, it is preferable that the curve of the depletion layer is minimized and more preferable that the depletion layer occurring between the trenches is not separated but connected.

However, when the ratio (W1/W2) is set within 1 to 2, the interval W2 between the trenches 2 need secure a certain width to prevent the connection of the emitter layers 7. Therefore, in order to set the ratio (W1/W2) within 1 to 2, it is necessary to increase the width W1 of the trench 2 for that purpose. However, when the width W1 of the trench 2 is increased, the depletion layer between the adjacent trenches 2 is more likely to separate and curve by this increasing amount. Therefore, the breakdown voltage under the conditions a to g is evaluated.

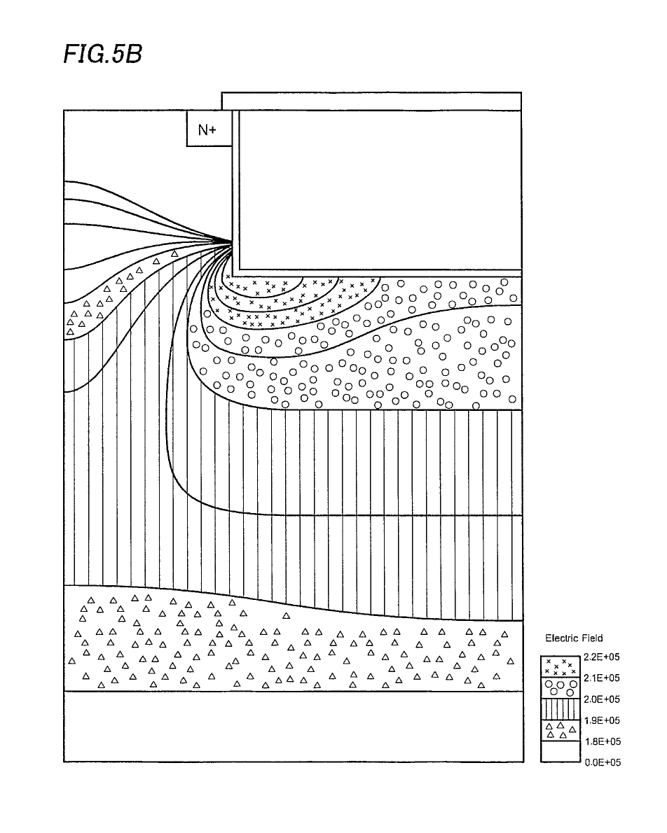

FIGS. 5A and 5B show distribution maps of a depletion layer upon application of a voltage of 600 V. FIG. 5A shows a distribution map in a case of the ratio (W1/W2) of 0.3, and FIG. 5B shows a distribution map in a case of the ratio (W1/W2) of 1.3.

Referring to FIG. 5A, when the ratio (W1/W2) is 0.3, although the depletion layer curves and the field intensity is maximum in a portion A immediately under the trench 2, the depletion layer is not separated but connected between the trenches 2.

Referring to FIG. 5B, even when the ratio (W1/W2) is 1.3, almost all the depletion layer is not separated but connected between the trenches 2. This is because the NPT structure of the embodiment has high breakdown voltage characteristics. In detail, when a high voltage is applied, the depletion layer largely expands accordingly. The large expanding depletion layer is easy to connect between the trenches 2. It is noted that at the end portions B of the trench 2 the depletion layer between the trenches 2 is separated and curves. However, the field intensity in these portions is seen to be almost equal to that in the portion A immediately under the trench 2 in FIG. 5A.

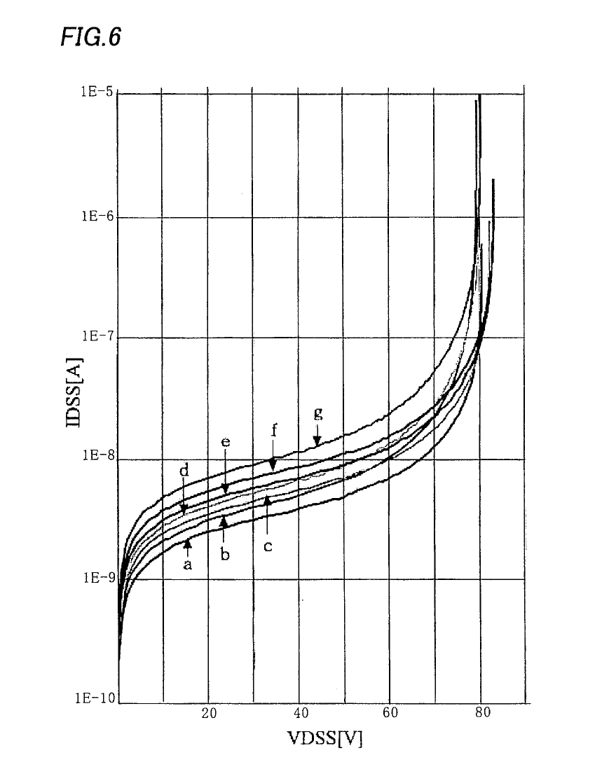

Furthermore, FIG. 6 shows waveforms of an emitter-collector breakdown voltage in the IGBT having a breakdown voltage of 600 V.

Referring to FIG. 6, the waveforms of the breakdown voltage do not vary largely in the range of the conditions a to g.

As described above, it is found that in the NPT structure having a high breakdown voltage the reduction of the breakdown voltage is hardly found in the range of the conditions a to g.

It is to be understood that this disclosed embodiment is illustrative and not limitative in all regards. The scope of the invention is defined by claims and not by the above description of the embodiment, and includes equivalents to the claims and all modifications within the scope of the invention.

For example, the NPT-type IGBT 1 is described in the above embodiment. However, the invention is not limited to this and also similarly applicable to IGBT having other structure such that a buffer layer is formed between a collector layer and a drift layer as long as a collector layer is formed by ion implantation. This IGBT may be thinner than the IGBT 1 of the embodiment as a whole.

Furthermore, although the IGBT having a breakdown voltage of 600V is described in the above described embodiment, the invention is not limited to this. In detail, the invention becomes more effective in the IGBT having a high breakdown voltage higher than 600 V since the curve of the depletion layer is reduced more.

In the insulated gate bipolar transistor of the invention, even if it has the NPT structure, the IGBT of the embodiment minimizes reduction of electron current density, prevents a variation in characteristics, and attains a sufficient conductivity modulation effect.

What is claimed is:

1. A non-punch-through type insulated gate bipolar transistor comprising:
a collector layer of a first general conductive type;
a drift layer of a second general conductive type formed on the collector layer;
a base layer of the first general conductive type formed on the drift layer;
a plurality of insulated gates formed from in the base layer so as to reach the drift layer; and
an emitter layer of the second general conductive type formed in a surface portion of the base layer adjacent the insulated gates,
wherein a lateral width of the insulated gate is larger than a minimum distance between a lateral edge of one insulated gate and a lateral edge of another insulated gate that is next to said one insulated gate.

2. The insulated gate bipolar transistor of claim 1, wherein the lateral width of the insulated gate is less than twice the minimum distance.

3. The insulated gate bipolar transistor of claim 1, wherein the collector layer comprises impurities of the first general conductivity type implanted in a layer of the second general conductivity type.
